(19) United States
(12) Patent Application Publication
(10) Pub. No.: US 2008/0145977 A1
(43) Pub. Date: Jun. 19, 2008

(54) Increasing the resistance of a high frequency input/output power delivery decoupling path

(76) Inventors: Xiang Yin Zeng, Shanghai (CN); Guo Yan, Tempe, Arizona (CN); Jiangqi He, Gilbert, Arizona (CN)

Correspondence Address: TROP PRUNER & HU, PC, 1616 S. VOSS ROAD, SUITE 750, HOUSTON, TX, 77057-2631, US

(21) Appl. No.: 11/640,568

(22) Filed: Dec. 18, 2006

(51) Int. Cl. H01L 21/82

(52) U.S. Cl. 438/128

(57) ABSTRACT

A conductive path, such as a copper patch, between decoupling capacitors and a high frequency integrated circuit, may be oxidized to improve the power delivery performance. Specifically, adding the resistance in the conductive path by oxidizing the conductive path increases the dampening of the peak impedance at a given peak frequency. In some embodiments, a mask may be used to control the amount of the conductive path that is oxidized.

### BACKGROUND

This relates generally to the delivery of power and input/output signals to integrated circuits such as processors.

A large number of input and output signals must be provided to integrated circuits. Highly complex integrated circuits, such as microprocessors, require a large number of inputs and outputs, as well as power and ground connections. Because of the high frequency that these devices operate at, special considerations must be addressed. For example, one such consideration is achieving a steady voltage at an acceptable processor transient response. One of the methods for responding to a processor transient is to place a high performance capacitor as close to the processor as possible to shorten the transient response time.

The power delivery performance may be characterized by its impedance with frequency sweep, which is usually called Z(f). An ideal power delivery network has a flat impedance line across all frequency ranges with a minimal impedance value. Realistically, Z(f) varies with frequency and, therefore, does not result in a flat, straight curve across the entire frequency spectrum. Instead, the input impedance increases at particular frequency ranges.

The higher the input impedance peak, the worse the power delivery network performance will be. Therefore, it is desirable to reduce that peak value of input impedance. Generally, decoupling capacitors are used to reduce the peak value, but the capacitors may be expensive and may take up a lot of space. Another approach is to reduce the power delivery network's loop inductance. While this is advantageous, it may be difficult to further improve the power delivery network performance by reducing loop inductance. Another approach is to add resistance in the decoupling path to damp the peak.

### BRIEF DESCRIPTION OF THE DRAWINGS

FIG. 1 is an enlarged, cross-sectional view of one embodiment of the present invention;

FIG. 2 is an enlarged, cross-sectional view taken generally along the line 2-2 in FIG. 1 in accordance with one embodiment of the present invention;

FIG. 3 is an enlarged, cross-sectional view of the embodiment shown in FIG. 1 at an earlier stage of manufacture; and

FIG. 4 is a system depiction in accordance with one embodiment of the present invention.

### DETAILED DESCRIPTION

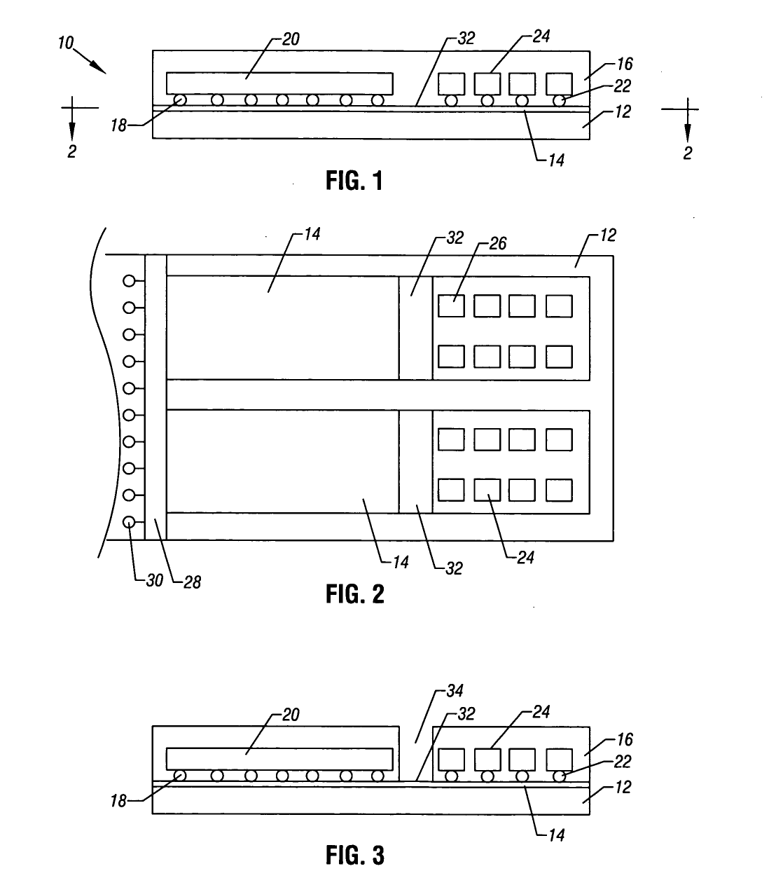

Referring to FIG. 1, a packaged integrated circuit 10, such as a central processing unit or microprocessor, may include a substrate 12. The substrate 12 may be made of a polymer, such as a resin including epoxy or polyimide, or a ceramic material, such as a low dielectric constant material or polybenzoxazole, to give a few examples. Over the substrate 12 may be a conductive path 14. The conductive path 14 may be a copper patch formed by plating copper on the substrate 12, for example, using electroplating, deposition, or electroless plating. However, any conductive path may be used that may be exposed and oxidized so that its resistance changes materially.

On top of the conductive path 14 are die side capacitors 24 that may be coupled by solder balls or bumps 22 to the conductive path 14. The die side capacitors 24 are part of the power delivery network that supplies power to the integrated circuit 10.

The path 14 couples the die side capacitors 24 to the integrated circuit chip 20. The integrated circuit chip 20 may be a processor, for example, such as a microprocessor, an embedded processor, or a digital signal processor, to give a few examples. In one embodiment, solder balls or bumps 18 may be utilized to couple the integrated circuit 20 to the substrate 12 and the path 14. However, any other connection technique may be utilized as well, including socket connections, pin connections, ball grid array connections, etc. Formed over the entire package is an encapsulation 16 such as an overmold or solder resist. The encapsulation 16 protects the finished structure.

A region 32 on the upper surface of the path 14 may be oxidized. As a result of such oxidation, the resistance of the path 14 to current flow between capacitors 24 and the chip 20 may be dramatically increased in some embodiments. This resistance may act as a damping resistor to reduce the peak value of input impedance at a given range of frequencies to improve the power delivery network's performance. Moreover, no additional structure may be needed, in some embodiments, to achieve this damping.

In particular, where the path 14 is formed of copper, the oxidation of copper forms CuO, which may have a relatively high resistivity. For example, in some embodiments, CuO may have a resistivity of 21 Ohm per centimeter which is about six times higher than the resistance of pure copper. This will greatly increase the impedance, improving performance in some cases. In other words, by adding resistance to the decoupling path, the peak input impedance may be dampened.

Referring to FIG. 2, the upper surface of the substrate 12 may have a plurality of paths 14 formed thereon. In the case illustrated in FIG. 2, two paths 14 coupled to die side capacitors 24 through lands 26 on one side and on the other side connect to the integrated circuit die 20 through pads 30 coupled by a conductive bar 28.

The oxidized region 32 may be located in the conductive path, coupling the die side capacitors 24 to the integrated circuit 20, thereby adding resistance to the decoupling path. The oxidized region 32 may extend completely across the upper surface of each path 14, in one embodiment. The extent of oxidation on the area of oxidation may be tailored to achieve a desired impedance.

Turning next to FIG. 3, in accordance with one embodiment of the present invention, the oxidation may be done after encapsulating the package 10. This has the advantage of not needing to open up contacts, after masking, to the chip 20 or the capacitors 16. However, in other embodiments, the path 14 may be masked and oxidized prior to formation or assembly of either or both of the capacitors 24 and chip 20. In some embodiments, the encapsulation 16 may be replaced with other masking materials, including any conventional mask material.

An opening 34 may be formed through the encapsulation 16 to allow an oxidizing environment to contact and oxidize the path 14 where exposed. In some embodiments, the oxidation may be done using oxygen, but any suitable oxidant may be utilized. In addition, temperature may be applied to enhance the oxidation effects.

The extent of oxidation and the size of the oxidation may be tailored to achieve the desired dampening resistance. The opening 34 may be filled in or closed off in some embodiments.

In another embodiment, the conductive path 14 may couple an integrated voltage regulator to an integrated circuit. The integrated voltage regulator may include integrated capacitors, a pulse width modulation circuit, and inductors, all in one integrated circuit package.

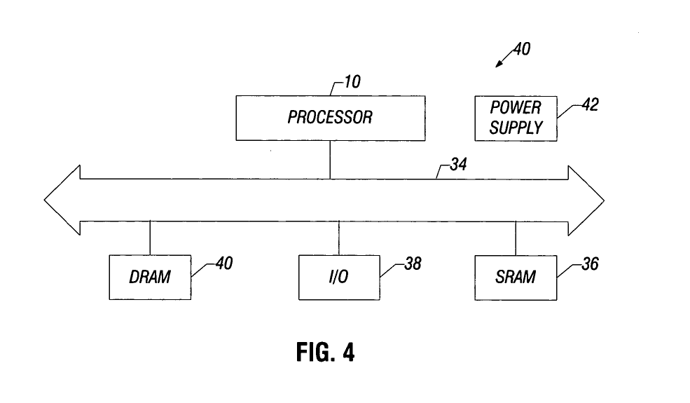

Referring to FIG. 4, in accordance with some embodiments of the present invention, a computer system 40 may be formed using the package 10 shown in FIG. 1. Particularly, a packaged processor may be coupled by a bus 34 to various other components such as dynamic random access memory (DRAM) 40, input/output (I/O) devices 38, and static random access memory (SRAM) 36. A suitable power supply 42 may supply power to the processor 10 and the other components through the die side capacitors 24.

In some embodiments of the present invention, any processor-based system may be formed. Thus, the embodiment shown in FIG. 4 is merely an example. By improving the power delivery network performance, the performance of an integrated circuit at high frequencies may be improved. In some embodiments, this may be done at relatively low cost and with relatively low process complexity.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a conductive path between a decoupling capacitor and an integrated circuit; and
oxidizing the conductive path to increase the resistance of that path.

2. The method of claim 1 including oxidizing only a portion of the path.

3. The method of claim 1 including oxidizing completely across said path.

4. The method of claim 1 wherein said path includes copper and oxidizing to form CuO.

5. The method of claim 1 including tailoring the extent of oxidation to achieve a desired damping resistance.

6. The method of claim 1 including forming said conductive path as a copper patch on a substrate.

7. The method of claim 6 including mounting said capacitor on said substrate.

8. The method of claim 7 including mounting said capacitor on said copper patch.

9. The method of claim 6 including mounting said integrated circuit on said substrate.

10. The method of claim 9 including mounting said integrated circuit on said copper patch.

11. The method of claim 1 including oxidizing said path after securing said capacitor and said circuit to said path.

12. An integrated circuit package comprising:
an integrated circuit;
a decoupling capacitor; and
a conductive path between said capacitor and said circuit, said path including an oxidized region to provide a damping resistance.

13. The package of claim 12 wherein said circuit is a processor.

14. The package of claim 12 including a substrate mounting said capacitor and said circuit.

15. The package of claim 12 wherein said path is on said substrate.

16. The package of claim 15 wherein said path includes a copper patch.

17. The package of claim 16 wherein said capacitor and said circuit are coupled electrically to said patch.

18. The package of claim 17 wherein said circuit and said capacitor are surface mounted on said patch.

19. The package of claim 17 wherein said circuit is covered by encapsulation.

20. The package of claim 19 including a trench through said encapsulation to said patch.

21. The package of claim 20, said oxidized region aligned with said trench.

22. A system comprising:
a processor;
a dynamic random access memory coupled to said processor;
a decoupling capacitor; and
a conductive path electrically coupling said capacitor and said processor, said path including an oxidized region.

23. The system of claim 22 including a substrate mounting said capacitor and said circuit.

24. The system of claim 22 wherein said path is on said substrate.

25. The system of claim 24 wherein said path includes a copper patch.
